(19) United States
(12) Patent Application Publication
(10) Pub. No.: US 2026/0231322 A1
(43) Pub. Date: Aug. 6, 2026

(54) COMPOSITE ELECTRONIC COMPONENT

(71) Applicant: TDK CORPORATION, Tokyo (JP)

(72) Inventors: Kazutoshi TSUYUTANI, Tokyo (JP); Naoyuki ISHIKAWA, Tokyo (JP)

(21) Appl. No.: 19/151,184

(22) PCT Filed: Jan. 23, 2023
(86) PCT No.: PCT/JP2024/001797

§ 371 Date: Jul. 25, 2025

(30) Foreign Application Priority Data
Feb. 8, 2023 (JP) 2023-017292

(51) Int. Cl. H05K 1/02; H05K 1/03; H05K 1/16; H05K 3/46

(52) U.S. Cl. CPC H05K 1/0271; H05K 1/0259; H05K 1/0373; H05K 1/165; H05K 3/4644; H05K 3/4697; H05K 2201/068

(57) ABSTRACT

To enhance, in a composite electronic component having a structure in which an electronic component is embedded in an insulating layer, adhesion between the electronic component and the insulating layer. A composite electronic component includes an insulating layer positioned between first and second wiring structures and an ESD protection component embedded in the insulating layer. The insulating layer includes two insulating layers. One insulating layer is formed by a mixture of a binder resin and filler. The ESD protection component has a main surface contacting a surface of an insulating layer, a back surface contacting a surface of an insulating layer, and a side surface. There is formed a fillet of an adhesion layer formed of the same resin material as the binder resin at a corner formed by the surface and side surface. This enhances adhesion between the ESD protection component and the insulating layer.

### TECHNICAL FIELD

The present disclosure relates to a composite electronic component and, more particularly, to a composite electronic component having an insulating layer in which an electronic component is embedded.

### BACKGROUND ART

Patent Document 1 discloses a printed wiring board having a structure in which an electronic component is embedded in an insulating layer.

### CITATION LIST

### Patent Document

[Patent Document 1] JP 2015-226013A

### DISCLOSURE OF THE INVENTION

### Problem to be Solved by the Invention

In the printed wiring board described in Patent Document 1, there is a risk that adhesion between the electronic component and the insulating layer may be insufficient.

The present disclosure relates to a composite electronic component having a structure in which an electronic component is embedded in an insulating layer and describes a technology for enhancing adhesion between the electronic component and the insulating layer.

### Means for Solving the Problem

A composite electronic component according to one aspect of the present disclosure includes: first and second wiring structures; an insulating layer positioned between the first wiring structure and the second wiring structure; and an electronic component embedded in the insulating layer. The insulating layer includes a first insulating layer having a first surface and a second insulating layer having a second surface that partially contacts the first surface, and the second insulating layer is made of a mixture containing at least a binder resin and filler. The electronic component has a main surface covered with the second insulating layer, a back surface positioned on the opposite side of the main surface and contacting the first surface of the first insulating layer, and a side surface connecting the main surface and the back surface. A fillet of an adhesion layer made of the same resin material as the binder resin contained in the second insulating layer at a corner formed by the first surface of the first insulating layer and the side surface of the electronic component is formed.

### Advantageous Effects of the Invention

According to the present disclosure, an adhesion between the electronic component and the insulating layer can be enhanced in a composite electronic component having a structure in which an electronic component is embedded in an insulating layer.

### BRIEF DESCRIPTION OF THE DRAWINGS

FIG. 1 is a schematic perspective view illustrating the outer appearance of a composite electronic component 1 according to an embodiment of the technology described herein.

FIG. 2 is a schematic cross-sectional view of the composite electronic component 1.

FIG. 3 is an exploded perspective view of the composite electronic component 1.

FIG. 4 is a schematic plan view illustrating the shapes of the conductor patterns provided in the conductor layer C4.

FIG. 5 is a schematic plan view illustrating the shapes of the conductor patterns provided in the conductor layer C3.
FIG. 6 is a schematic plan view illustrating the shapes of the conductor patterns provided in the conductor layer C2.

FIG. 7 is a schematic plan view of the layer in which the ESD protection component 2 is embedded.

FIG. 8 is a schematic plan view illustrating the shapes of the conductor patterns provided in the conductor layer C1.

FIG. 9 is a schematic plan view illustrating the shapes of the conductor patterns provided in the conductor layer C0.

FIG. 10 is an equivalent circuit diagram of the composite electronic component 1.

FIG. 11 is a process view for explaining the manufacturing method for composite electronic component 1.

FIG. 12 is a process view for explaining the manufacturing method for composite electronic component 1.

FIG. 13 is a process view for explaining the manufacturing method for composite electronic component 1.

FIG. 14 is a process view for explaining the manufacturing method for composite electronic component 1.

FIG. 15 is a process view for explaining the manufacturing method for composite electronic component 1.

FIG. 16 is a process view for explaining the manufacturing method for composite electronic component 1.

FIG. 17 is a process view for explaining the manufacturing method for composite electronic component 1.

FIG. 18 is a process view for explaining the manufacturing method for composite electronic component 1.

FIG. 19 is a process view for explaining the manufacturing method for composite electronic component 1.

FIG. 20 is a process view for explaining the manufacturing method for composite electronic component 1.

FIG. 21 is a process view for explaining the manufacturing method for composite electronic component 1.

FIG. 22 is a process view for explaining the manufacturing method for composite electronic component 1.

FIG. 23 is a process view for explaining the manufacturing method for composite electronic component 1.

### MODE FOR CARRYING OUT THE INVENTION

Hereinafter, some embodiments of the present invention will be described in detail with reference to the accompanying drawings.

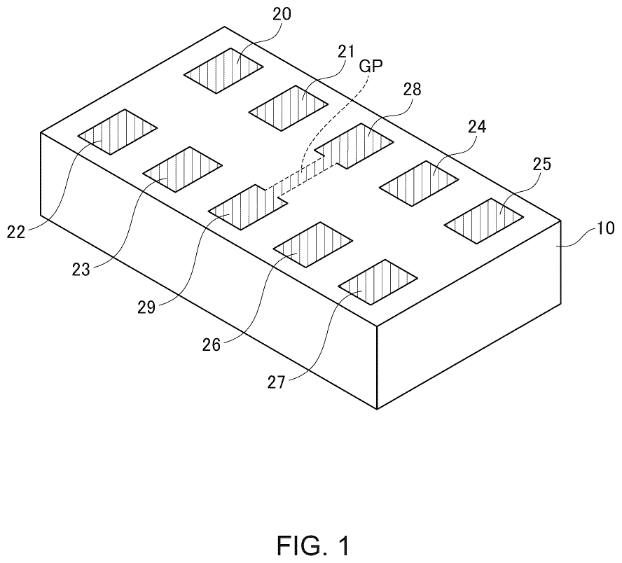

FIG. 1 is a schematic perspective view illustrating the outer appearance of a composite electronic component 1 according to an embodiment of the technology described herein.

The composite electronic component 1 according to the present embodiment is a surface-mounted chip component and has, as illustrated in FIG. 1, an element body 10 and a plurality of external terminals arranged in an array in the surface of the element body 10. The plurality of external terminals includes eight signal terminals 20 to 27 and two ground terminals 28 and 29.

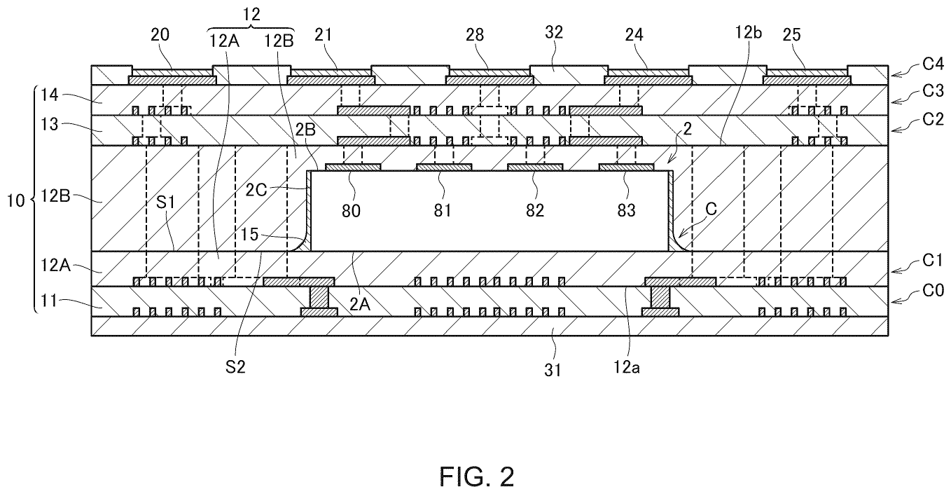

FIG. 2 is a schematic cross-sectional view of the composite electronic component 1.

As illustrated in FIG. 2, the element body 10 has a structure in which insulating layers 11 to 14 made of resin or the like are stacked in this order. The insulating layer 11 is provided on one surface side (surface 12a side) of the insulating layer 12, and the insulating layers 13 and 14 are provided on the other surface side (surface 12b side) of the insulating layer 12. A conductor layer C1 is formed between the surface 12a of the insulating layer 12 and the insulating layer 11. A conductor layer C0 is formed on the surface of the insulating layer 11. The conductor layer C0 is covered with a solder resist 31. The insulating layer 11 and the conductor layers C0 and C1 formed on both surfaces of the insulating layer 11 c0nstitutes a first wiring structure. The conductor layers C0 and C1 are embedded respectively in the insulating layers 11 and 12. As a result, the flatness of the outermost surface of the first wiring structure becomes higher than when the conductor layer C0 is provided so as to protrude from the surface of the insulating layer 11, thus making it possible to ensure sufficient insulation performance even when the thickness of the solder resist 31 is reduced. Although one insulating layer 11 is included in the first wiring structure in the example illustrated in FIG. 2, the number of layers of the insulating layers included in the first wiring structure is not particularly limited.

A conductor layer C2 is formed between the surface 12b of the insulating layer 12 and the insulating layer 13. The conductor layer C2 is covered with the insulating layer 13. A conductor layer C3 is formed on the surface of the insulating layer 13. The conductor layer C3 is covered with the insulating layer 14. A conductor layer C4 is formed on the surface of the insulating layer 14. The conductor layer C4 is covered with a solder resist 32. The insulating layers 13 and 14 and the conductor layers C2 to C4 formed on both surfaces of each of the insulating layers 13 and 14 constitute a second wiring structure. The conductor layers C2 and C3 are embedded respectively in the insulating layers 13 and 14. On the other hand, the conductor layer C4 protrudes from the surface of the insulating layer 14. Although two insulating layers 13 and 14 are included in the second wiring structure in the example illustrated in FIG. 2, the number of layers of the insulating layers included in the second wiring structure is not particularly limited.

The insulating layers 11 to 14 are each an interlayer film having conductor layers on its front and back and, in that sense, the solder resists 31 and 32 each do not correspond to the insulating layer. Thus, it can be said that the insulating layers 11 and 14 are outermost insulating layers. In the example illustrated in FIG. 2, the solder resist 31 covers the entire outermost surface of the insulating layer 11. Thus, in this example, the conductor layer C0 is not exposed but is covered with the solder resist 31. On the other hand, the solder resist 32 partially has openings, and a part of the conductor layer C4 that is exposed from each of the openings is used as the external terminal.

An ESD protection component 2 is embedded in the insulating layer 12. The ESD protection component 2 is constituted by a semiconductor substrate and thus differs in coefficient of thermal expansion from the insulating layers 11 to 14. In the example illustrated in FIG. 2, the ESD protection component 2 is positioned at substantially the center in the stacking direction, and the insulating layers 11, 13, and 14 are provided on both sides of the ESD protection component 2, so that the degree of freedom when the symmetry in the stacking direction is adjusted by adjusting the thickness is high, thus making it unlikely to cause warpage of the entire composite electronic component 1 due to temperature change.

The insulating layer 12 includes insulating layers 12A and 12B stacked one on the other. The insulating layer 12A has a surface S1 positioned on the opposite side of the surface 12a of the insulating layer 12, and the insulating layer 12B has a surface S2 positioned on the opposite side of the surface 12b of the insulating layer 12. The insulating layers 12A and 12B are stacked one on the other such that the surfaces S1 and S2 face each other and partially contact each other. The ESD protection component 2 is positioned between the insulating layers 12A and 12B. As a result, the surface S2 of the insulating layer 12B has a step-like shape following the shape of the ESD protection component 2. The insulating layers 12A and 12B are each formed by a mixture containing at least a binder resin and filler. The insulating layers 12A and 12B may be formed of the same material. Although the filler is not particularly limited in type, it may be an inorganic material having a low coefficient of thermal expansion, such as silica.

The ESD protection component 2 has a main surface 2B on which the plurality of terminal electrodes including terminal electrodes 80 to 83 are formed, a back surface 2A positioned on the opposite side of the main surface 2B, and a side surface 2C connecting the main surface 2B and back surface 2A. In the example illustrated in FIG. 2, the side surface 2C is formed perpendicular to the main surface 2B and back surface 2A. The shape of the ESD protection component 2 is not limited to this, but may be, for example, a substantially trapezoid in substantially the cross-sectional view of FIG. 2 or a rounded rectangular having slightly rounded corners. The ESD protection component 2 is embedded in the insulating layer 12 such that the back surface 2A contacts the surface S1 of the insulating layer 12A and that the main surface 2B contacts the surface S2 of the insulating layer 12B. An adhesion layer 15 is formed between at least a part of the side surface 2C of the ESD protection component 2 and the insulating layer 12B. The adhesion layer 15 contains the same resin material as the binder resin contained in at least one of the insulating layers 12A and 12B. The binder resin contained in the adhesion layer 15 may be the same resin material as that contained in both the insulating layers 12A and 12B.

The adhesion layer 15 acts to enhance adhesion between the ESD protection component 2 and the insulating layer 12, and a fillet of the adhesion layer 15 is formed at a corner C formed by the surface S1 of the insulating layer 12A and the side surface 2C of the ESD protection component 2. As a result, the corner C where voids are likely to occur is filled with the adhesion layer 15. Further, the surface of the adhesion layer 15 that contacts the insulating layer 12B has a concave shape, so that it is possible to extend the contact area between the insulating layer 12B and the adhesion layer 15 while ensuring an adequate volume for the insulating layer 12B.

The adhesion layer 15 may contain or not contain filler. When the adhesion layer 15 contains filler, the filler contained in the adhesion layer 15 may be the same material as the filler contained in both the insulating layers 12A and 12B. Further, when the adhesion layer 15 contains filler, it is possible to ensure sufficient adhesion of the adhesion layer 15 by making the content density of the filler in the adhesion layer 15 lower than the content density of the filler in the insulating layers 12A and 12B. The adhesion of the adhesion layer 15 becomes higher as the content density of the filler becomes lower. The insulating layers 12A and 12B are higher in the filler content density than the adhesion layer 15 and are thus lower in coefficient of thermal expansion than the adhesion layer 15, whereby the occurrence of warpage can be suppressed. The coefficient of thermal expansion of the insulating layer 12A may be the same as that of the insulating layer 12B; however, by making lower the coefficient of thermal expansion of the insulating layer 12B having a larger volume than that of the insulating layer 12A, occurrence of warpage can be suppressed more effectively.

Further, in the example illustrated in FIG. 2, the entire side surface 2C of the ESD protection component 2 is covered with the adhesion layer 15, whereby adhesion between the ESD protection component 2 and the insulating layer 12 is further enhanced. However, the technology according to the present disclosure is not limited to this. For example, it is sufficient that at least a part of the side surface 2C of the ESD protection component 2 is covered with the adhesion layer 15. To achieve sufficient adhesion between the ESD protection component 2 and the insulating layer 12, a half or more of the area of the side surface 2C is preferably covered with the adhesion layer 15, for example.

The width (length in a direction parallel to the layers constituting the composite electronic component 1) of the ESD protection component 2 in the horizontal direction larger than the thickness (height in the stacking direction of the composite electronic component 1) of the ESD protection component 2. In some cases, the width of the ESD protection component 2 is about ten time larger than the thickness. Therefore, the influence of coefficient of thermal expansion is larger in the horizontal direction (direction parallel to the layers constituting the composite electronic component 1) than in the stacking direction. When the adhesion layer 15 is provided on the side surface 2C of the ESD protection component 2, it is possible to reduce the influence of coefficient of thermal expansion more effectively than when the adhesion layer 15 is provided, for example, on the main surface 2B or back surface 2A of the ESD protection component 2. Further, as illustrated in FIG. 2, by providing the adhesion layer 15 at the corner C where three members of the insulating layer 12A, insulating layer 12B, and ESD protection component 2, it is possible to improve adhesion more effectively and ESD protection component 2 and to reduce the influence of coefficient of thermal expansion.

When the entire ESD protection component 2 is covered with the adhesion layer 15 with a smaller amount of filler than the insulating layer 12B, mechanical strength may be reduced more than when the entire ESD protection component 2 is covered with the insulating layer not through the adhesion layer 15. For example, the adhesion layer 15 is not provided on the main surface 2B or back surface 2A but is formed to the corner C or on the side surface 2C including the corner C, whereby adequate mechanical strength and adhesion can be achieved.

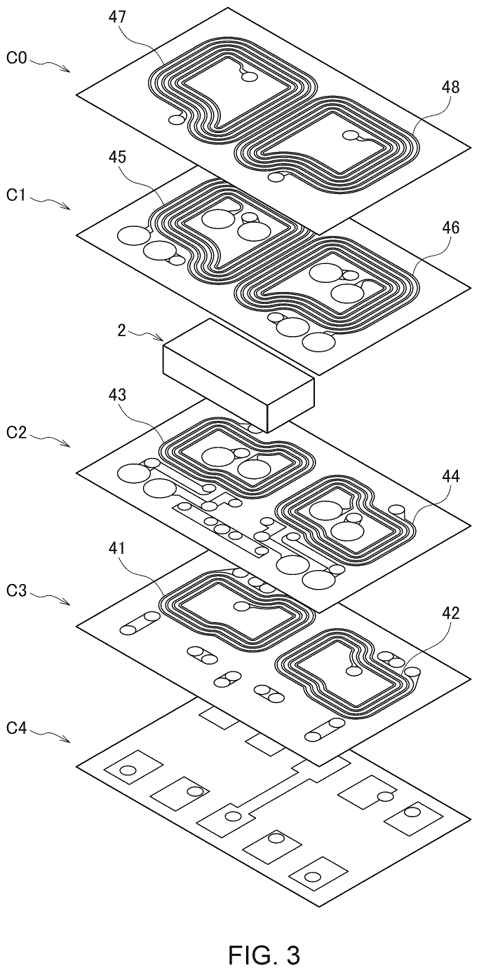

FIG. 3 is an exploded perspective view of the composite electronic component 1.

As illustrated in FIG. 3, coil patterns 41 to 48 are embedded in the composite electronic component 1. The coil patterns 41 and 42 are disposed in the conductor layer C3, coil patterns 43 and 44 are disposed in the conductor layer C2, coil patterns 45 and 46 are disposed in the conductor layer C1, and coil patterns 47 and 48 are disposed in the conductor layer C0. The coil patterns 41 and 43 overlap each other in a plan view through the insulating layer 13, and the coil patterns 42 and 44 overlap each other in a plan view through the insulating layer 13. The coil patterns 45 and 47 overlap each other in a plan view through the insulating layer 11, and coil patterns 46 and 48 overlap each other in a plan view through the insulating layer 11.

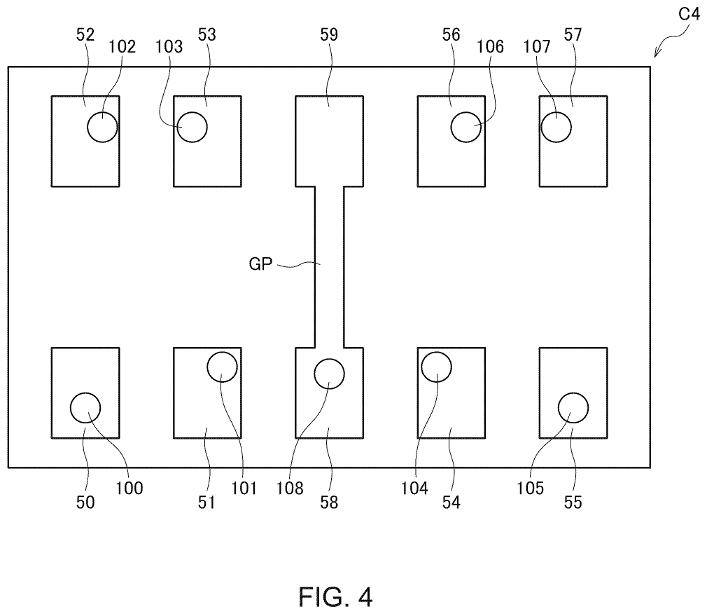

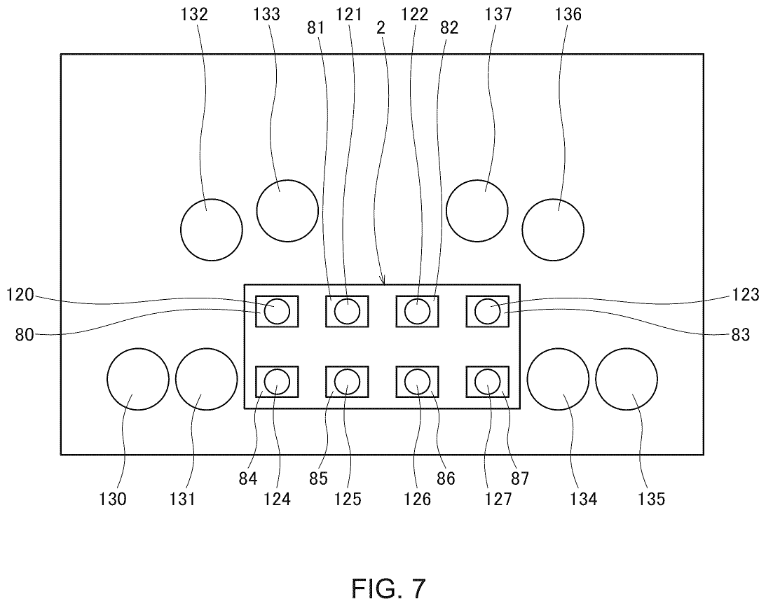

FIGS. 4 to 6, 8, and 9 are schematic plan views respectively illustrating the shapes of the conductor patterns provided in the conductor layers C4, C3, C2, C1, and C0. FIG. 7 is a schematic plan view of the layer in which the ESD protection component 2 is embedded.

As illustrated in FIG. 4, the conductor layer C4 has conductor patterns 50 to 59 and a ground pattern GP. The exposed parts of the conductor patterns 50 to 57 from the solder resist 32 are subjected to surface treatment and used as signal terminals 20 to 27, respectively. The exposed parts of the conductor patterns 58 and 59 from the solder resist 32 are subjected to surface treatment and used as ground terminals 28 and 29, respectively. The conductor patterns 58 and 59 are connected to each other through the ground pattern GP. The ground pattern GP is a linearly extending conductor pattern and has a width smaller than those of the conductor patterns 58 and 59. As described above, the ground pattern GP, signal terminals 20 to 27, and conductor patterns 58 and 59 are disposed in the same conductor layer (conductor layer C4), thus eliminating the need of providing an additional conductor layer for the ground pattern GP.

As illustrated in FIG. 5, the conductor layer C3 has the coil patterns 41 and 42 and conductor patterns 60, 61, and 63 to 66. The outer peripheral end of the coil pattern 41 is connected to the conductor pattern 52 through a via conductor 102. The outer peripheral end of the coil pattern 42 is connected to the conductor pattern 57 through a via conductor 107. The conductor patterns 60, 61, and 63 to 66 are connected respectively to the conductor patterns 50, 51, and 53 to 56 through respective via conductors 100, 101, and 103 to 106 formed in the insulating layer 14. The coil patterns 41 and 42 are disposed adjacent to each other with a gap G1 therebetween. In the conductor layer C3, a ground pattern and the like are not provided in the gap G1, and the coil patterns 41 and 42 are directly adjacent to each other through the insulating layer 14.

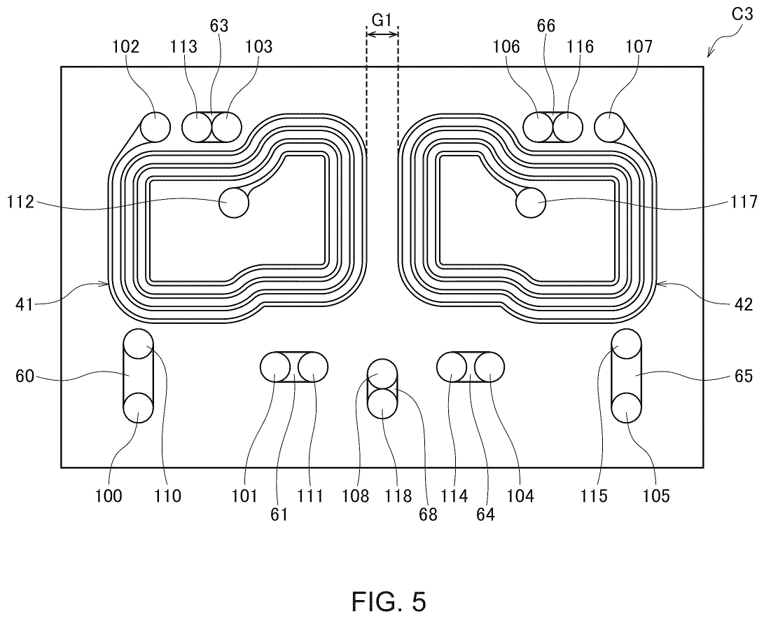

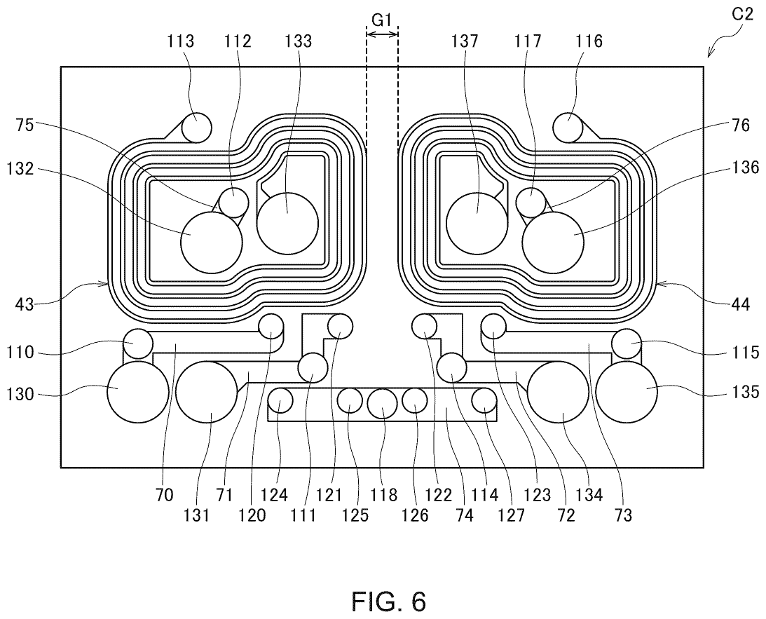

As illustrated in FIG. 6, the conductor layer C2 has the coil patterns 43 and 44 and conductor patterns 70 to 76. The outer peripheral end of the coil pattern 43 is connected to the conductor pattern 63 through a via conductor 113. The outer peripheral end of the coil pattern 44 is connected to the conductor pattern 66 through a via conductor 116. The conductor patterns 70 to 74 are connected respectively to the conductor patterns 60, 61, 64, 65, and 68 through respective via conductors 110, 111, 114, 115, and 118. The conductor patterns 75 and 76 are connected respectively to the inner peripheral ends of the coil patterns 41 and 42 through via conductors 112 and 117. The coil patterns 43 and 44 are disposed adjacent to each other with the gap Gl therebetween. In the conductor layer C2, a ground pattern and the like are not provided in the gap G1, and the coil patterns 43 and 44 are directly adjacent to each other through the insulating layer 13.

The coil patterns 41 to 44 each have a configuration in which the conductor patterns are wound in about four turns. The coil patterns 41 and 43 overlap each other in the stacking direction and substantially coincide with each other excluding the positions of the outer and inner peripheral ends. Similarly, the coil patterns 42 and 44 overlap each other in the stacking direction £ and substantially coincide with each other excluding the positions of the outer and inner peripheral ends. Further, in a plan view, the coil patterns 41 and 42 are symmetric to each other in terms of the pattern shape and, similarly, the coil patterns 43 and 44 are symmetric to each other in terms of the pattern shape.

As illustrated in FIG. 7, terminal electrodes 80 to 87 are provided on the surface of the ESD protection component 2. The terminal electrodes 80 to 83 are connected respectively to the conductor patterns 70 to 73 through respective via conductors 120 to 123 formed in the insulating layer 12. The terminal electrodes 84 to 87 are connected in common to the conductor pattern 74 through respective via conductors 124 to 127 formed in the insulating layer 12.

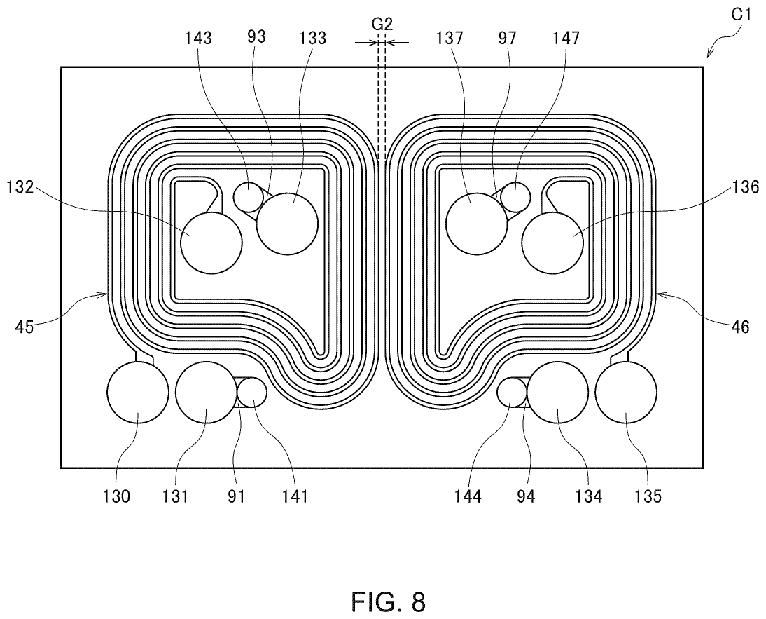

As illustrated in FIG. 8, the conductor layer Cl has the coil patterns 45 and 46 and conductor patterns 91, 93, 94, and 97. The outer peripheral end of the coil pattern 45 is connected to the conductor pattern 70 through a via conductor 130. The outer peripheral end of the coil pattern 46 is connected to the conductor pattern 73 through a via conductor 135. The inner peripheral end of the coil pattern 45 is connected to the conductor pattern 75 through a via conductor 132. The inner peripheral end of the coil pattern 46 is connected to the conductor pattern 76 through a via conductor 136. The conductor patterns 91 and 94 are connected respectively to the conductor patterns 71 and 72 through respective via conductors 131 and 134. The conductor patterns 93 and 97 are connected respectively to the inner peripheral ends of the coil patterns 43 and 44 through respective via conductors 133 and 137. The coil patterns 45 and 46 are disposed adjacent to each other with a gap G2 therebetween. In the conductor layer C1, a ground pattern and the like are not provided in the gap G2, and the coil patterns 45 and 46 are directly adjacent to each other through the insulating layer 12.

As illustrated in FIG. 9, the conductor layer C0 has the coil patterns 47 and 48. The outer and inner peripheral ends of the coil pattern 47 are connected respectively to the conductor patterns 91 and 93 through respective via conductors 141 and 143. The outer and inner peripheral ends of the coil pattern 48 are connected respectively to the conductor patterns 94 and 97 through respective via conductors 144 and 147. The coil patterns 47 and 48 are disposed adjacent to each other with the gap G2 therebetween. In the conductor layer C0, a ground pattern and the like are not provided in the gap G2, and the coil patterns 47 and 48 are directly adjacent to each other through the insulating layer 11.

The coil patterns 45 to 48 each have a configuration in which the conductor patterns are wound in about five turns. The coil patterns 45 and 47 overlap each other in the stacking direction and substantially coincide with each other excluding the positions of the outer and inner peripheral ends. Similarly, the coil patterns 46 and 48 overlap each other in the stacking direction and substantially coincide with each other excluding the positions of the outer and inner peripheral ends. Further, in a plan view, the coil patterns 45 and 46 are symmetric to each other in terms of the pattern shape and, similarly, the coil patterns 47 and 48 are symmetric to each other in terms of the pattern shape.

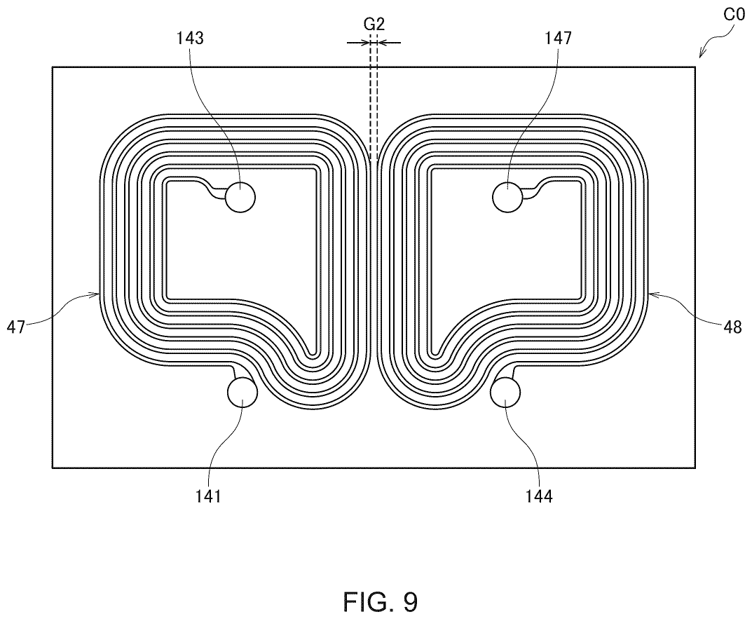

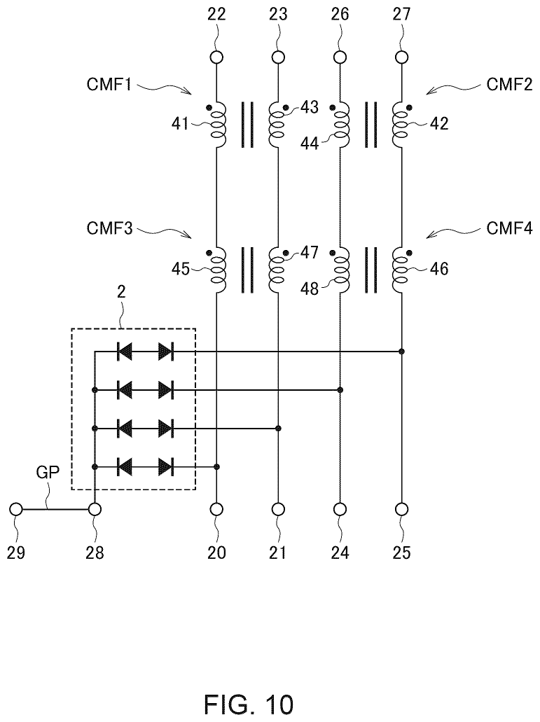

FIG. 10 is an equivalent circuit diagram of the composite electronic component 1 according to the present embodiment.

In the composite electronic component 1 illustrated in FIG. 10, the coil patterns 45 and 41 are connected in series between signal terminals 20 and 22, coil patterns 47 and 43 are connected in series between the signal terminals 21 and 23, coil patterns 48 and 44 are connected in series between the signal terminals 24 and 26, and coil patterns 46 and 42 are connected in series between the signal terminals 25 and 27. The coil patterns 41 and 43 are magnetically coupled to each other to constitute a common mode filter CMF1, coil patterns 42 and 44 are magnetically coupled to each other to constitute a common mode filter CMF2, coil patterns 45 and 47 are magnetically coupled to each other to constitute a common mode filter CMF3, and coil patterns 46 and 48 are magnetically coupled to each other to constitute a common mode filter CMF4. Further, protective elements integrated in the ESD protection component 2 are inserted between the signal terminals 20, 21, 24, 25 and the ground terminals 28, 29. As a result, the composite electronic component 1 illustrated in FIG. 10 constitutes a common mode filter array with ESD protective function. The ground terminal 29 is connected to the ESD protection component 2 through the ground pattern GP.

As described above, the composite electronic component 1 according to the present embodiment is configured such that the ESD protection component 2 is not simply embedded in the insulating layer 12, but the fillet of the adhesion layer 15 is formed at the corner C formed by the surface S1 of the insulating layer 12A and the side surface 2C of the ESD protection component 2, so that adhesion between the ESD protection component 2 and the insulating layer 12 is enhanced to make it possible to suppress the occurrence of voids at the corner C. This prevents the characteristics of the common mode filters CMF3 and CMF4 included in the first wiring structure and the characteristics of the common mode filters CMF1 and CMF2 included in the second wiring structure from changing due to voids, peeling of the ESD protection component 2, and the like, thus increasing product reliability.

The following describes a manufacturing method for the composite electronic component 1 according to the present embodiment.

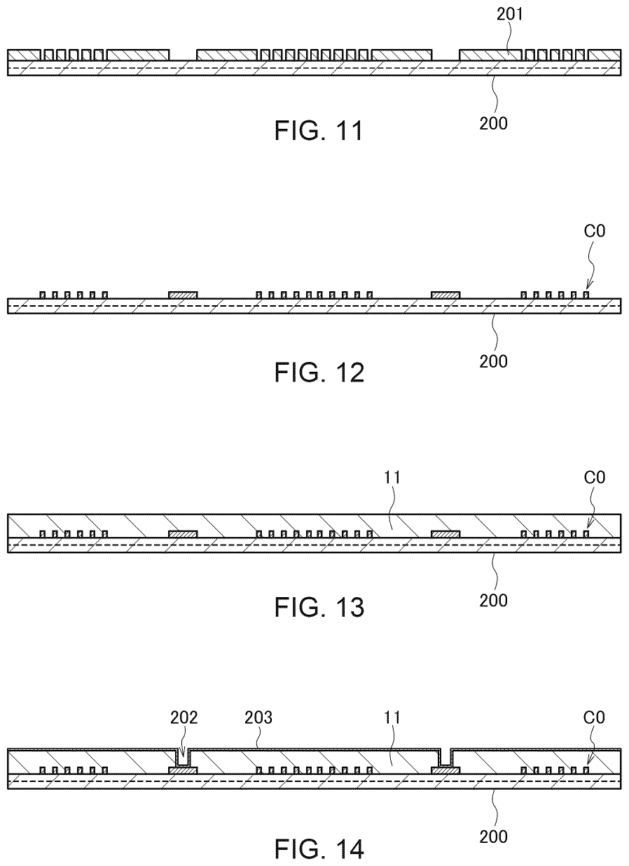

FIGS. 11 to 23 are process views for explaining the manufacturing method for composite electronic component 1 according to the present embodiment.

First, a carrier-attached copper foil 200 is prepared, and a resist pattern 201 is formed on the surface thereof (FIG. 11). The carrier-attached copper foil 200 has a structure in which a release layer is provided between two layers of copper foil. The resist pattern 201 is a negative pattern of the conductor layer C0. In this state, electrolytic plating is performed, followed by removal of the resist pattern 201, whereby the conductor layer C0 is formed (FIG. 12). Subsequently, the insulating layer 11 is formed on the surface of the carrier-attached copper foil 200 so as to embed therein the conductor layer Co (FIG. 13). As a result, the side and upper surfaces of the conductor pattern positioned in the conductor layer C0 are covered with the insulating layer 11.

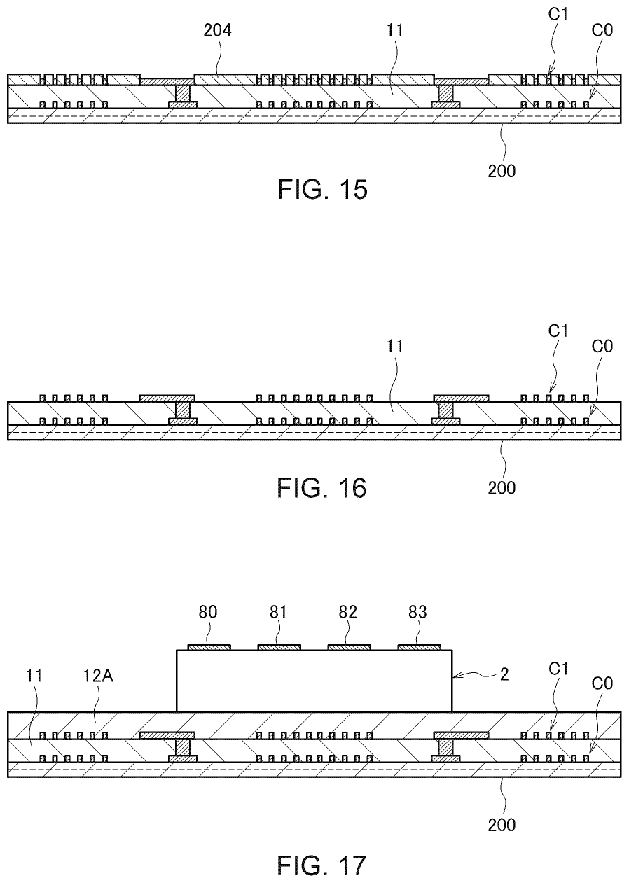

Then, a via 202 is formed at the formation position of a via conductor to expose a part of the conductor layer C0, and electroless plating is performed to form a seed layer 203 on the surface of the insulating layer 11 (FIG. 14). Subsequently, a resist pattern 204 is formed on the surface of the seed layer 203, and electrolytic plating is performed to form the conductor layer C1 (FIG. 15). Subsequently, after removal of the resist pattern 204 (FIG. 16), the insulating layer 12A is formed on the surface of the insulating layer 11 so as to embed therein the conductor layer C1, and the ESD protection component 2 is mounted on the surface of the insulating layer 12A (FIG. 17). As a result, the side and upper surfaces of the conductor pattern positioned in the conductor layer Cl are covered with the insulating layer 12A.

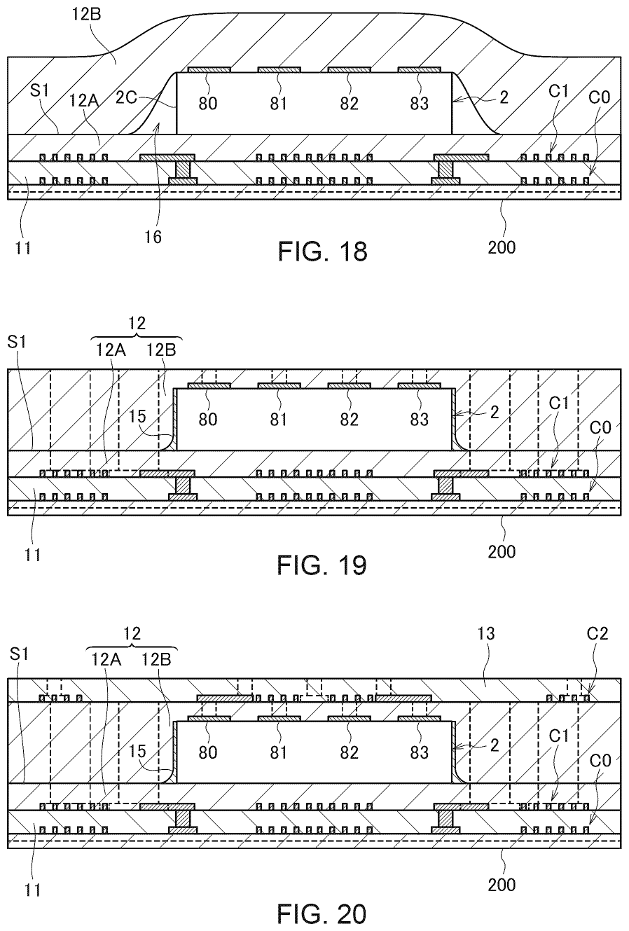

Then, a semi-cured sheet-like insulating layer is prepared as the insulating layer 12B and placed on the surface S1 of the insulating layer 12A so as to cover the ESD protection component 2 (FIG. 18). At this point in time, there is a clearance 16 between the side surface 2C of the ESD protection component 2 and the insulating layer 12B. When the insulating layer 12B is immediately subjected to curing in such a condition, the clearance 16 may not completely filled up. Further, since the side surface 2C of the ESD protection component 2 and the insulating layer 2B directly contact each other, even if the clearance 16 is completely filled up, adhesion between the ESD protection component 2 and the insulating layer 12B may become insufficient due to the presence of filler contained in the insulating layer 12B. Thus, curing conditions of the insulating layer 12B are adjusted so as to form the filler in the adhesion layer 15.

Specifically, after the lamination of the sheet-like insulating layer 12B, heating temperature for the insulating layer 12B is gradually increased under depressurized conditions to reduce the clearance 16 and to make the binder resin contained in the insulating layer 12B e into the clearance 16. The resin oozing constitutes the adhesion layer 15. At this time, a state where the temperature is lower than a curing temperature needs to be kept so as to prevent the binder resin from being cured before the clearance 16 is completely filled up with the adhesion layer 15. Then, after the elapse of a sufficient time for the clearance to be filled up with the adhesion layer 15, the insulating layer 12B is heat-cured while being pressurized. As a result, the ESD protection component 2 is embedded in the insulating layer 12 (12A and 12B), and the fillet of the adhesion layer 15 is formed at the corner C formed by the surface S1 of the insulating layer 12A and the side surface 2C of the ESD protection component 2 (FIG. 19).

When the binder resin oozes from the insulating layer 12B into the clearance 16, the filler content density in the insulating layer 12B becomes slightly higher than that in the initial state, resulting in further reduction in the coefficient of thermal expansion. On the other hand, the filler content density in the insulating layer 12A does not substantially change before and after embedding of the ESD protection component 2. Thus, in terms of the final coefficient of thermal expansion, the insulating layer 12B is slightly lower than the insulating layer 12A under the condition that the insulating layers 12A and 12B are formed of the same material.

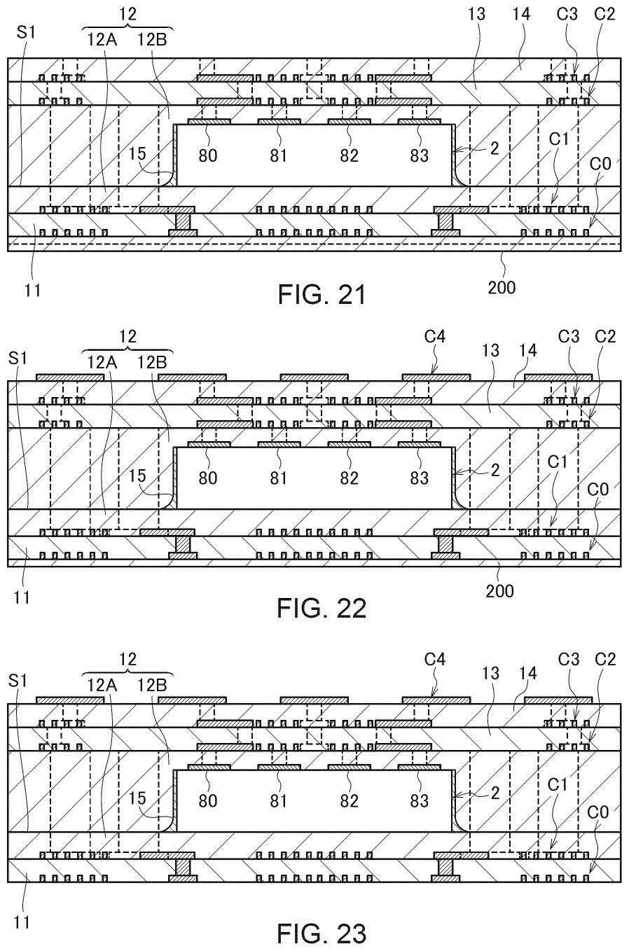

Then, the processes described using FIGS. 14 to 16 are repeated to form the conductor layer C2 on the surface of the insulating layer 12, and the insulating layer 13 is formed on the surface of the insulating layer 12 so as to embed therein the conductor layer C2 (FIG. 20). This process is repeated again to form the conductor layer C3 on the surface of the insulating layer 13, and the insulating layer 14 is formed on the surface of the insulating layer 13 so as to embed therein the conductor layer C3 (FIG. 21). Subsequently, after the formation of the conductor layer C4 on the surface of the insulating layer 14, the copper foil 200 is peeled by one layer through the release layer included in the carrier-attached copper foil 200 (FIG. 22), and the remaining layer of the copper foil 200 is removed by etching (FIG. 23). Through this etching, the seed layer used for formation of the conductor layer C4 is also removed. Subsequently, the solder resists 31 and 32 are formed respectively on the outermost surfaces of the insulating layers 11 and 14, and the signal terminals 21 to 27 and ground terminals 28 and 29 are formed through surface treatment, whereby the composite electronic component 1 is completed.

As described above, in the manufacturing process of the composite electronic component 1, the sheet-like insulating layer 12B is slowly heated under depressurized conditions after being laminated such that the binder resin included therein oozes into the clearance 16, thus allowing the clearance 16 to be filled up with the adhesion layer 15.

While the preferred embodiment of the present disclosure has been described, the present disclosure is not limited to the above embodiment, and various modifications may be made within the scope of the present disclosure, and all such modifications are included in the present disclosure.

For example, although the ESD protection component 2 is embedded in the insulating layer 12 in the above embodiment, an electronic component to be embedded in the insulating layer 12 is not limited to this.

The technology according to the present disclosure includes the following configuration examples but not limited thereto.

A composite electronic component according to one aspect of the present disclosure includes: first and second wiring structures; an insulating layer positioned between the first wiring structure and the second wiring structure; and an electronic component embedded in the insulating layer. The insulating layer includes a first insulating layer having a first surface and a second insulating layer having a second surface that partially contacts the first surface, and the second insulating layer is made of a mixture containing at least a binder resin and filler. The electronic component has a main surface covered with the second insulating layer, a back surface positioned on the opposite side of the main surface and contacting the first surface of the first insulating layer, and a side surface connecting the main surface and the back surface. A fillet of an adhesion layer made of the same resin material as the binder resin contained in the second insulating layer at a corner formed by the first surface of the first insulating layer and the side surface of the electronic component is formed. This enhances adhesion between the electronic component and the insulating layer.

In the above composite electronic component, the adhesion layer may be made of a mixture containing the same resin material as the binder resin contained in the second insulating layer and filler contained in the second insulating layer, and the second insulating layer may be higher in filler content density and lower in coefficient of thermal expansion than the adhesion layer. This makes it possible to enhance adhesion of the adhesion layer and to suppress warpage of the entire substrate.

In the above composite electronic component, the first insulating layer may be formed by a mixture containing at least a binder resin and filler, and the first insulating layer may be higher in filler content density and lower in coefficient of thermal expansion than the adhesion layer. This makes it possible to enhance adhesion of the adhesion layer and to further suppress warpage of the entire substrate.

In the above composite electronic component, the binder resin contained in the first insulating layer, the binder resin contained in the second insulating layer, and the binder resin contained in the adhesion layer may be the same resin material. This enhances adhesion between the first insulating layer, second insulating layer, and adhesion layer.

In the above composite electronic component, the filler contained in the first insulating layer, the filler contained in the second insulating layer, and the filler contained in the adhesion layer may be the same inorganic material. This reduces material cost.

In the above composite electronic component, the second insulating layer may be lower in coefficient of thermal expansion than the first insulating layer. Thus, when the second insulating layer is thicker than the first insulating layer, warpage of the entire substrate can further be suppressed.

In the above composite electronic component, the surface of the adhesion layer that contacts the second insulating layer may have a concave shape. This makes it possible to extend the contact area between the second insulating layer and the adhesion layer while ensuring a sufficient volume for the second insulating layer.

In the above composite electronic component, the adhesion layer may cover the entire side surface of the electronic component. This further enhances adhesion between the electronic component and the adhesion layer.

This application claims the benefit of Japanese Patent Application No. 2023-017292, filed on Feb. 8, 2023, the entire disclosure of which is incorporated by reference herein.

### REFERENCE SIGNS LIST

1 composite electronic component
2 ESD protection component (electronic component)
2A back surface
2B main surface
2C side surface
10 element body
11-14, 12A, 12B insulating layer
12a, 12b surface of insulating layer
20-27 signal terminal
28, 29 ground terminal
31, 32 solder resist
41-48 coil pattern
50-59 conductor pattern
60, 61, 63-66, 68 conductor pattern
70-76 conductor pattern
80-87 terminal electrode
91, 93, 94, 97 conductor pattern
100-107, 110-118, 120-127, 130-137, 141, 143, 144, 147 via conductor
200 carrier-attached copper foil
201 resist pattern
202 via
203 seed layer
204 resist pattern
C corner
C0-C4 conductor layer
CMF1-CMF4 common mode filter
G1, G2 gap
GP ground pattern
S1, S2 surface

1. A composite electronic component comprising:
first and second wiring structures;
an insulating layer positioned between the first wiring structure and the second wiring structure; and
an electronic component embedded in the insulating layer,
wherein the insulating layer includes a first insulating layer having a first surface and a second insulating layer having a second surface that partially contacts the first surface,
wherein the second insulating layer is made of a mixture containing at least a binder resin and filler,
wherein the electronic component has a main surface covered with the second insulating layer, a back surface positioned on an opposite side of the main surface and contacting the first surface of the first insulating layer, and a side surface connecting the main surface and the back surface,
wherein a fillet of an adhesion layer made of a same resin material as the binder resin contained in the second insulating layer at a corner formed by the first surface of the first insulating layer and the side surface of the electronic component is formed.

2. The composite electronic component as claimed in claim 1,
wherein the adhesion layer is made of a mixture containing the same resin material as the binder resin contained in the second insulating layer and the filler contained in the second insulating layer, and
wherein the second insulating layer is higher in filler content density and lower in coefficient of thermal expansion than the adhesion layer.

3. The composite electronic component as claimed in claim 2,
wherein the first insulating layer is made of a mixture containing at least a binder resin and filler, and
wherein the first insulating layer is higher in filler content density and lower in coefficient of thermal expansion than the adhesion layer.

4. The composite electronic component as claimed in claim 3, wherein the binder resin contained in the first insulating layer, the binder resin contained in the second insulating layer, and the binder resin contained in the adhesion layer are a same resin material.

5. The composite electronic component as claimed in claim 4, wherein the filler contained in the first insulating layer, the filler contained in the second insulating layer, and the filler contained in the adhesion layer are a same inorganic material.

6. The composite electronic component as claimed in claim 3, wherein the second insulating layer is lower in coefficient of thermal expansion than the first insulating layer.

7. The composite electronic component as claimed in claim 1, wherein a surface of the adhesion layer that contacts the second insulating layer has a concave shape.

8. The composite electronic component as claimed in claim 1, wherein the adhesion layer covers an entire side surface of the electronic component.
